(19) United States
(12) Patent Application Publication
(10) Pub. No.: US 2021/0288738 A1
(43) Pub. Date: Sep. 16, 2021

(54) SYSTEMS AND METHODS FOR TIME, NETWORK TRAFFIC, AND CABLE MANAGEMENT

(71) Applicant: Facebook, Inc., Menlo Park, CA (US)

(72) Inventors: Ahmad Byagowi, Mountain View, CA (US); Andrei Lukovenko, Dublin (IE); Huapeng Zhou, Mountain View, CA (US); Yair Gottdenker, Los Altos, CA (US); Alan H. Frindell, Seattle, WA (US); Roberto Javier Peon, Mercer Island, WA (US); Luca Niccolini, San Francisco, CA (US); Yang Chi, New York, NY (US); Matthew Hansen Joras, Seattle, WA (US); Chenyu Xu, Hayward, CA (US); Blanche Sydney Christina Chisholm, Oakland, CA (US); Shawn Blanchard, Marana, AZ (US); Hao-Yun Ma, San Jose, CA (US); Wei-Ta Peng, Union City, CA (US)

(21) Appl. No.: 17/336,998

(22) Filed: Jun. 2, 2021

Related U.S. Application Data
(60) Provisional application No. 63/132,539, filed on Dec. 31, 2020.
(60) Provisional application No. 63/144,663, filed on Feb. 2, 2021.
(60) Provisional application No. 63/148,254, filed on Feb. 11, 2021.
(60) Provisional application No. 63/150,804, filed on Feb. 18, 2021.
(60) Provisional application No. 63/150,794, filed on Feb. 18, 2021.

(51) Int. Cl. H04J 3/06; H05K 7/18

(52) U.S. Cl. CPC H04J 3/0697; H05K 7/186; H04J 3/0641; H04J 3/0667

(57) ABSTRACT

The disclosed systems and methods may include a network device for evaluating, developing, and benchmarking a precision time protocol network. Additionally, the disclosed systems and methods may be directed to utilizing direct server return for content delivery network traffic. The disclosed apparatus may include a grommet and a clip, where the grommet includes an opening shaped to hold at least one cable such as a medusa cable and a groove around an outer diameter of the grommet. The disclosed apparatuses, systems, and methods may include an apparatus for organizationally distributing cables to rackmount network devices. Various other methods, systems, and computer-readable media are also disclosed.

### CROSS-REFERENCE TO RELATED APPLICATIONS

This application claims the benefits of U.S. Provisional Application No. 63/132,539, filed Dec. 31, 2020, U.S. Provisional Application No. 63/144,663, filed Feb. 2, 2021, U.S. Provisional Application No. 63/148,254, filed Feb. 11, 2021, U.S. Provisional Application No. 63/150,804, filed Feb. 18, 2021, and U.S. Provisional Application No. 63/150,794, filed Feb. 18, 2021, the disclosures of each of which are incorporated, in their entirety, by this reference.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a block diagram of an exemplary system for a precision time protocol (PTP) network-in-a-box.

FIG. 2 is a block diagram of an exemplary system for a compact version of the PTP network-in-a-box described in FIG. 1.

FIG. 3 is a flow diagram of an exemplary method for using a PTP network-in-a-box.

FIG. 4A is a block diagram of an exemplary system for utilizing direct server return to deliver cached network content.

FIG. 4B is a block diagram of an exemplary system including a direct server return architecture to deliver cached network content.

FIG. 4C is a communication chart for utilizing direct server return to deliver cached network content.

FIG. 4D is a flow diagram of an exemplary method for utilizing direct server return to deliver cached network content.

FIG. 5A illustrates an example over-molding grommet.

FIG. 5B illustrates an example of mounting a grommet onto a medusa cable with zip ties.

FIGS. 5C-D illustrate a cable clip redirecting feature that may accommodate an offset angle.

FIG. 5E illustrates a medusa cable secured in a chassis by a grommet and cable clip.

FIGS. 5F-G illustrate a medusa cable secured in a chassis by a grommet and a Velcro strap.

FIG. 5H illustrates a medusa cable and chassis sub-assembly.

FIG. 5I illustrates a medusa cable managed and secured to a storage chassis.

FIG. 6A illustrates an exemplary apparatus for organizationally distributing cables to rackmount network devices.

FIG. 6B illustrates an exemplary system for organizationally distributing cables to rackmount network devices.

FIG. 7A illustrates an exemplary system for organizationally distributing cables to rackmount network devices.

FIG. 7B illustrates an exemplary system for organizationally distributing cables to rackmount network devices.

FIG. 7C illustrates an exemplary port arrangement incorporated into a system for organizationally distributing cables to rackmount network devices.

FIG. 7D illustrates an exemplary port arrangement incorporated into a system for organizationally distributing cables to rackmount network devices.

FIG. 7E illustrates an exemplary port arrangement incorporated into a system for organizationally distributing cables to rackmount network devices.

FIG. 7F illustrates an exemplary system for organizationally distributing cables to rackmount network devices.

FIG. 7G illustrates an exemplary system for organizationally distributing cables to rackmount network devices.

FIG. 7H illustrates an exemplary system for organizationally distributing cables to rackmount network devices.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

### PTP Network in a Box

Precision Time Protocol (PTP) networks may typically consist of multiple individual nodes representing various network devices/appliances that collaborate to perform a variety of tasks involving synchronizing multiple clocks to meet various metrics associated with conducting financial transactions (e.g., banking, high-speed trading, etc.) and/or other time-sensitive activities. Due to the precise timing utilized by PTP network devices, special timing equipment is often needed to measure time delays and other key performance indicators (KPIs) for identifying errors and evaluating network performance.

The use of timing equipment in current methods of evaluating PTP networks often involves simulating network timing. However, due to the complexity and nature of PTP networks, these simulations often fail to reflect the operation of actual PTP networks and thus may fail to accurately identify potential issues with time delays and/or KPIs for evaluating network performance.

The present disclosure is generally directed to a network device for evaluating, developing, and benchmarking a PTP network. As will be explained in greater detail below, embodiments of the present disclosure may include a network device that may serve as and/or replace a conventional multi-node PTP network (e.g., the network device represents a PTP network-in-a-box). The network device may include a primary network interface controller containing a master physical clock (e.g., a grandmaster clock) for receiving PTP signals. The network device may also include a group of secondary network interface controllers containing physical clocks (e.g., boundary or ordinary clocks) for receiving PTP signals. Individual network namespaces may be associated with the primary network interface controller and each of the secondary network interface controllers. The network device may further include network interfaces for synchronizing the PTP signals between the master physical clock and the boundary or ordinary physical clocks. Advantageously, a physical processor may be utilized to determine an accuracy measurement of PTP timing synchronization between the physical clocks by executing the network namespaces without the use of special timing equipment under non real-time (e.g., simulation) conditions.

Features from any of the embodiments described herein may be used in combination with one another in accordance with the general principles described herein. These and other embodiments, features, and advantages will be more fully understood upon reading the following detailed description in conjunction with the accompanying drawings and claims.

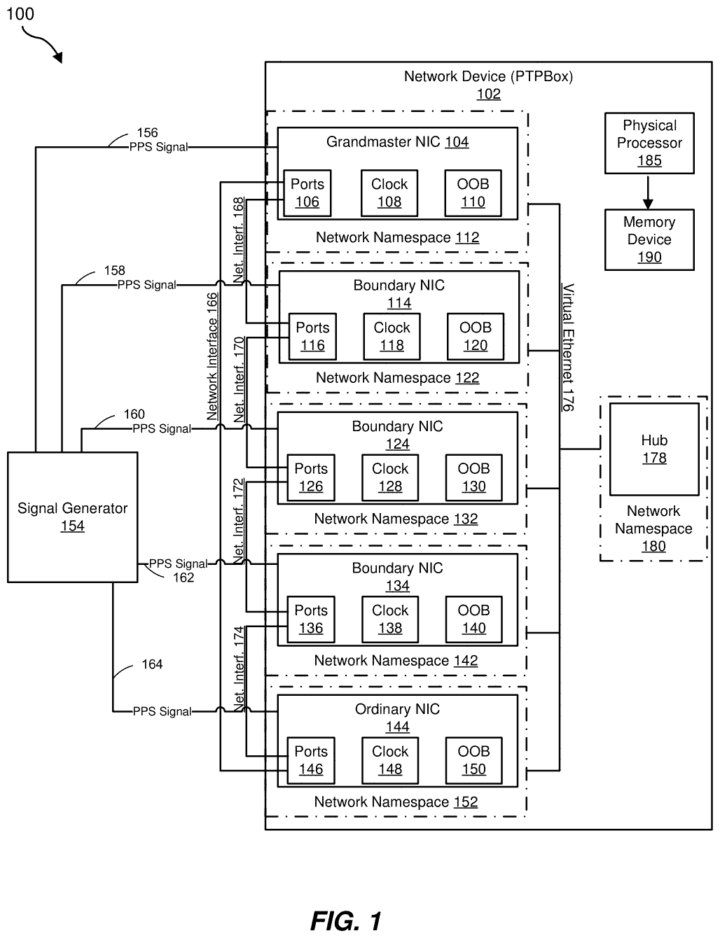

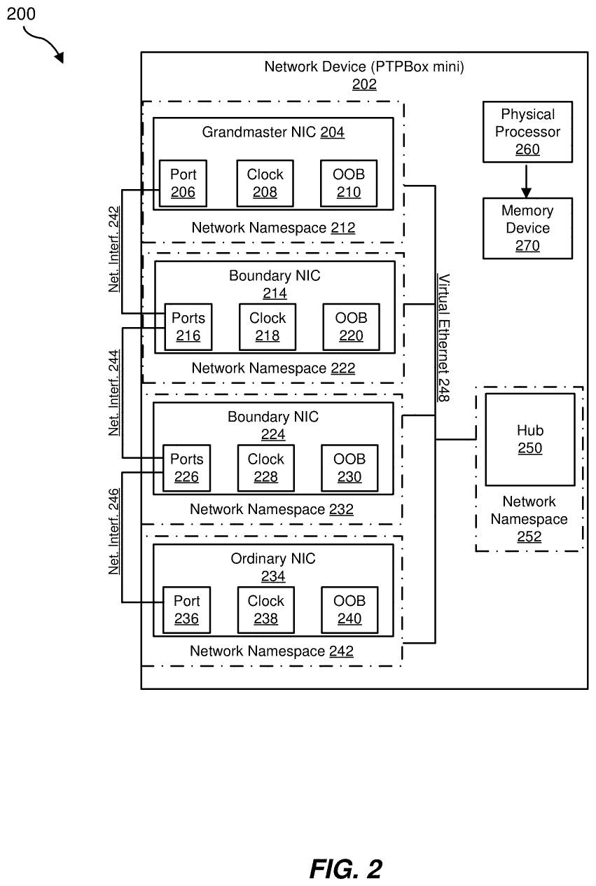

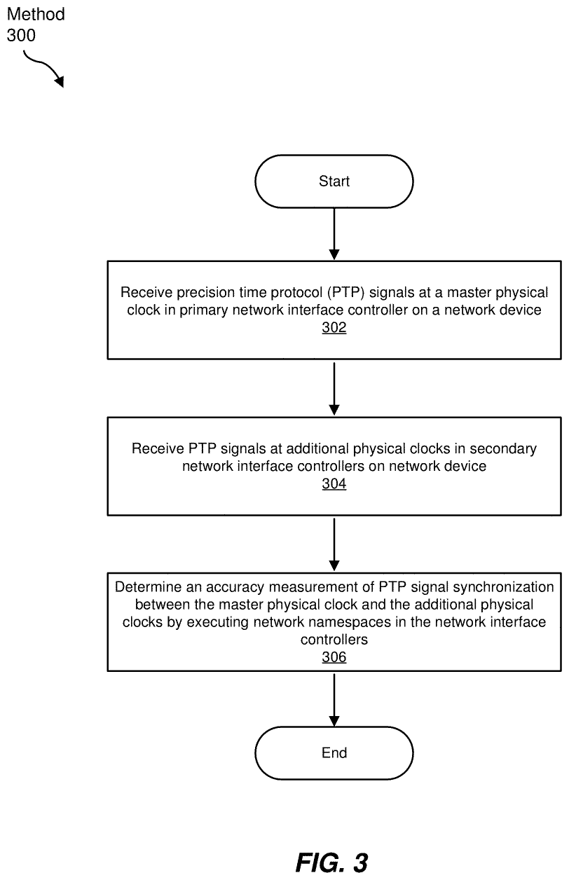

The following will provide, with reference to FIGS. 1-2, detailed descriptions of a PTP network-in-a-box. Detailed descriptions of a method for using the PTP network-in-a-box are provided with reference to FIG. 3

FIG. 1 shows a block diagram of a system 100 that may include a network device 102 connected to a signal generator 154. Network device 102 may include a physical processor 185 for executing instructions stored in a memory device 190. In some examples, network device 102 may be a computing device based on a Peripheral Component Interconnect Express (PCIe) 8× slotted motherboard configured to take advantage of Linux network namespaces (e.g., network namespaces 112, 122, 132, 142, 152, and 180).

Network device 102 may further include several network interface cards (NICs) including a grandmaster NIC 104, boundary NICs 114, 124, and 134, and ordinary NIC 144. As will be described in greater detail below, each of NICs 104, 114, 124, 134, and 144 may be isolated in separate network namespaces 112, 122, 132, 142, and 152, respectively. In some examples, grandmaster NIC 104 may contain a set of ports 106, a clock (e.g., a PTP grandmaster clock) 108, and an out-of-band (OOB) management module 110. Additionally, boundary NIC 114 may contain a set of ports 116, a PTP boundary clock 118, and an OOB management module 120. Additionally, boundary NIC 124 may contain a set of ports 126, a PTP boundary clock 128, and an OOB management module 130. Additionally, boundary NIC 134 may contain a set of ports 136, a PTP boundary clock 138, and an OOB management module 140. Finally, ordinary NIC 144 may contain a set of ports 146, a PTP ordinary clock 148, and an OOB management module 150.

In some examples, communications between grandmaster NIC 104, boundary NICs 114, 124, and 134, and ordinary NIC 144 may be enabled via network interfaces 166, 168, 170, 172, and 174 utilizing ports 106, 116, 126, 136, and 146. Network interfaces 166-174 may be 100 Gbps PTP network interfaces for communicating timing signals between grandmaster NIC 104, boundary NICs 114, 124, and 134, and ordinary NIC 144 via the physical network layer. For example, signal generator 154 may be configured to generate coax pulse-per-second (PPS) signals 156, 158, 160, 162, and 164 (e.g., 1 PPS) to an onboard GNSS receiver (not shown) on grandmaster NIC 104, boundary NICs 114, 124, and 134, and ordinary NIC 144.

Network device 102 may further include virtual ethernet connections 176 connecting network namespaces 112, 122, 132, 142, and 152 isolating grandmaster NIC 104, boundary NICs 114, 124, and 134, and ordinary NIC 144. Virtual ethernet connections 176 may also terminate into a hub 178 which is also isolated in network namespace 180.

In some examples, network namespaces 112, 122, 132, 142, 152, and 180 may be LINUX network namespaces created using the following commands for a network namespace called “GM” (i.e., a Grandmaster network namespace):

ip netns add <namespace name>

Ip netns add GM

ip netns list (for verifying that the network namespace has been created)

In some examples, utilizing network namespaces 112, 122, 132, 142, 152, and 180 enables different and separate instances of network interfaces and routing tables that operate independently of each other. Furthermore, having all of NICs 104-144 on a single machine (e.g., network device 102) enables access to all of clocks 108-148 (i.e., PTP Hardware Clocks (PHCs)) of NICs 104-144. Moreover, by utilizing CPU timestamping of PHC queries, a relatively accurate measurement of the synchronization of timing signals may be performed.

FIG. 2 shows a block diagram of a system 200 that may include a network device 202. Network device 202 may include a physical processor 260 for executing instructions stored in a memory device 270. In some examples, network device 202 may be a computing device based on a six NIC motherboard configured to take advantage of Linux network namespaces (e.g., network namespaces 212, 222, 232, 242, and 252).

Network device 202 may further include several network interface cards (NICs) including a grandmaster NIC 204, boundary NICs 214 and 224, and ordinary NIC 234. As will be described in greater detail below, each of NICs 204, 214, 224, and 234 may be isolated in separate network namespaces 212, 222, 232, and 242, respectively. In some examples, grandmaster NIC 204 may contain a set of ports 206, a clock (e.g., a PTP grandmaster clock) 208, and an out-of-band (OOB) management module 210. Additionally, boundary NIC 214 may contain a set of ports 216, a PTP boundary clock 218, and an OOB management module 220. Additionally, boundary NIC 224 may contain a set of ports 226, a PTP boundary clock 228, and an OOB management module 230. Finally, ordinary NIC 234 may contain a set of ports 236, a PTP ordinary clock 238, and an OOB management module 240.

In some examples, communications between grandmaster NIC 204, boundary NICs 214, and 224, and ordinary NIC 234 may be enabled via network interfaces 242, 244, and 246 utilizing ports 206, 216, 226, and 236. Network interfaces 242-246 may be 100 Gbps PTP network interfaces for communicating timing signals between grandmaster NIC 204, boundary NICs 214 and 224, and ordinary NIC 234 via the physical network layer. For example, a signal generator (not shown) may be coupled to ports 206-236 to generate coax PPS signals to grandmaster NIC 204, boundary NICs 214 and 224, and ordinary NIC 234.

Network device 202 may further include virtual ethernet connections 248 connecting network namespaces 212, 222, 232, and 242, thereby isolating grandmaster NIC 204, boundary NICs 214 and 224, and ordinary NIC 234. Virtual ethernet connections 248 may also terminate into a hub 250 which is also isolated in network namespace 252.

In some examples, network namespaces 212-252 may be LINUX network namespaces created using the commands described above with respect to FIG. 1. By utilizing network namespaces 212-252, different and separate instances of network interfaces and routing tables may be enabled that operate independently of each other. Furthermore, having all of NICs 204-234 on a single machine (e.g., network device s02) enables access to all of clocks 208-239 (i.e., PTP Hardware Clocks (PHCs)) of NICs 204-234. Moreover, by utilizing CPU timestamping of PHC queries, a relatively accurate measurement of the synchronization of timing signals may be performed. In some examples, network namespaces 212-242 may be run with servos and grandmaster clock threads to simulate two PTP enabled hops from grandmaster NIC 204 to ordinary NIC 234.

FIG. 3 is a flow diagram of an exemplary computer-implemented method 300 for using a PTP network-in-a-box. The steps shown in FIG. 3 may be performed by any suitable computer-executable code and/or computing system, including the systems illustrated in FIGS. 1-2. In one example, each of the steps shown in FIG. 3 may represent an algorithm whose structure includes and/or is represented by multiple sub-steps, examples of which will be provided in greater detail below.

As illustrated in FIG. 3, at step 302 one or more of the systems described herein may receive PTP signals at a master physical clock in primary network interface controller on a network device. For example, clock 108 (e.g., a grandmaster clock) of grandmaster NIC 104 isolated in network namespace 112 may receive PTP signals.

The systems described herein may perform step 302 in a variety of ways. For example, grandmaster NIC 104 isolated in network namespace 112 may receive PPS signal 156 from signal generator 154.

At step 304, one or more of the systems described herein may receive PTP signals at additional physical clocks in secondary network interface controllers on the network device. For example, clocks 118-138 (e.g., boundary clocks) of boundary NICs 114-134 isolated in network namespaces 122-142 may receive PTP signals. Additionally, clock 148 (e.g., an ordinary clock) of ordinary NIC 144 isolated in network namespace 152 may receive PTP signals.

The systems described herein may perform step 304 in a variety of ways. For example, boundary NICs 114-134 isolated in network namespaces 112-142 may receive PPS signals 156-162 from signal generator 154 at ports 116-136. Additionally, ordinary NIC 144 isolated in network namespace 152 may receive PPS signal 162 from signal generator 154.

At step 306, one or more of the systems described herein may determine an accuracy measurement of PTP signal synchronization between the master physical clock and the additional physical clocks by executing network namespaces in the network interface controllers. For example, an accuracy measurement may be determined of PTP signal synchronization between clock 108 on grandmaster NIC 104, clocks 118-138 on boundary NICs 114-134, and clock 148 on ordinary NIC 144 by executing network namespaces 112-152.

The systems described herein may perform step 306 in a variety of ways. For example, the accuracy measurement of PTP synchronization may be determined by generating one or more PTP queries for clock 108 on grandmaster NIC 104, clocks 118-138 on boundary NICs 114-134, and clock 148 on ordinary NIC 144 and then timestamping the PTP queries. Additionally, network namespaces 112-152 may be executed utilizing one or more threads (e.g., one or more master physical clock threads) to simulate multiple PTP-enabled hops from clock 108 to clocks 118-148.

Conventional evaluation of a PTP network with multiple nodes corresponding to various PTP network appliances requires special timing equipment devices for measuring time delays and other key performance indicators (KPIs), thereby making it difficult to accurately evaluate network timing under non-simulated conditions. The present disclosure describes evaluating, developing, and benchmarking a PTP network, all in one system. By utilizing LINUX network namespaces, a computing device equipped with multiple NICs may run multiple threads for every different NIC. The NICs are isolated in separate namespaces thus enabling them to communicate via the physical network layer. Since the PTP timing is based on a physical clock sitting on every NIC individually, the synchronization will be targeted to align these timers. Since all the machines are sitting on the same machine, the benchmarking and modification of code is facilitated.

### EXAMPLE EMBODIMENTS

### Example 1

A network device comprising: (i) a primary network interface controller comprising (a) a master physical clock for receiving precision time protocol (PTP) signals, (b) a plurality of secondary network interface controllers, each of the secondary network interface controllers comprising an additional physical clock for receiving the PTP signals and (c) a network namespace associated with the primary network interface controller, (ii) an additional network namespace associated with each of the secondary network interface controllers, (iii) at least one network interface utilized for synchronizing the PTP signals between the master physical clock in the primary network interface controller and the additional physical clocks in each of the secondary network interface controllers, and (iv) at least one physical processor that determines an accuracy measurement of PTP timing synchronization between the master physical clock in the primary network interface controller and each of the additional physical clocks in the secondary network interface controllers by executing the network namespace and the additional network namespaces.

### Example 2

The network device of example 1, wherein the network namespace and the additional network namespaces are executed utilizing one or more master physical clock threads to simulate a plurality of PTP-enabled hops from the master physical clock to at least one of the additional physical clocks.

### Example 3

The network device of examples 1 and 2, wherein the at least one of the additional physical clocks comprises a boundary clock.

### Example 4

The network device of any of examples 1-3, wherein the accuracy measurement of the PTP timing synchronization is determined by generating one or more PTP queries for the master physical clock and each of the additional physical clocks and timestamping the PTP queries.

### Example 5

The network device of any of examples 1-4, wherein the network namespace associated with the primary network interface controller isolates the primary network interface controller from the network namespace associated with each of the secondary network interface controllers.

### Example 6

The network device of any of examples 1-5, wherein the network namespace associated with each of the secondary network interface controllers isolates each of the secondary network interface controllers from each other.

### Example 7

The network device of any of examples 1-6, wherein at least one of the additional physical clocks comprises an ordinary clock.

### Example 8

The network device of any of examples 1-7, wherein the master physical clock comprises a grandmaster clock.

### Example 9

A method comprising (i) receiving precision time protocol (PTP) signals at a master physical clock in a primary network interface controller on a network device, (ii) receiving the PTP signals at additional physical clocks in secondary network interface controllers on the network device, and (iii) determining an accuracy measurement of PTP signal synchronization between the master physical clock and the additional physical clocks by executing network namespaces in the network interface controllers.

### Example 10

The method of example 9, wherein determining the accuracy measurement of the PTP signal synchronization comprises generating one or more PTP queries for the master physical clock and each of the additional physical clocks and timestamping the PTP queries.

### Example 11

The method of examples 9 and 10, wherein the network namespace and the additional network namespaces are executed utilizing one or more master physical clock threads to simulate a plurality of PTP-enabled hops from the master physical clock to at least one of the additional physical clocks.

### Direct Server Return for Delivery of Cached Network Content

Content delivery networks may typically utilize a distributed system architecture to deliver content (e.g., video, images, etc.) from a caching backend to downstream client devices for consumption by users. For example, a conventional content delivery network architecture may contain two primary logical components for delivering content: (1) a reverse proxy that is responsible for terminating connections from a client and (2) a caching server that is responsible for caching static content. Thus, in a typical request/response data flow for a conventional content delivery network architecture, the reverse proxy receives a content request from the client, forwards the content request to the caching server, fetches the requested content (e.g., cached content) from the caching server, and then delivers the cached content to the client.

However, as the reverse proxy in conventional content delivery network architectures has to fetch data from the caching server prior to sending the data to the client, additional overhead (e.g., network input/output and processing overhead) may be introduced on the egress path to the client due to the reverse proxy needing to communicate with the caching server. Thus, the efficiency of content delivery networks may be significantly reduced when utilized to delivery large amounts of content to clients for consumption.

The present disclosure is generally directed to utilizing direct server return for content delivery network traffic. As will be explained in greater detail below, embodiments of the present disclosure may include a reverse proxy server that receives a content request from a client device. The reverse proxy server may then establish a communication session with a caching server responsible for providing the content. The reverse proxy server may then enable direct server return (DSR) for the content request. The reverse proxy server may then send packet instructions to the caching server for directly sending the content to the client device utilizing DSR. Advantageously, by sending packet instructions to the caching server for directly providing the content to the client (and thus bypassing the reverse proxy server), processing overhead associated with communications between the reverse proxy server and the caching server may be significantly reduced as compared to conventional content delivery network architectures. In addition, embodiments of the present disclosure may improve the efficiency of a computing device (e.g., a reverse proxy sever) in a content delivery network by reducing a processing overhead utilized for delivering content from caching servers to client devices.

Features from any of the embodiments described herein may be used in combination with one another in accordance with the general principles described herein. These and other embodiments, features, and advantages will be more fully understood upon reading the following detailed description in conjunction with the accompanying drawings and claims.

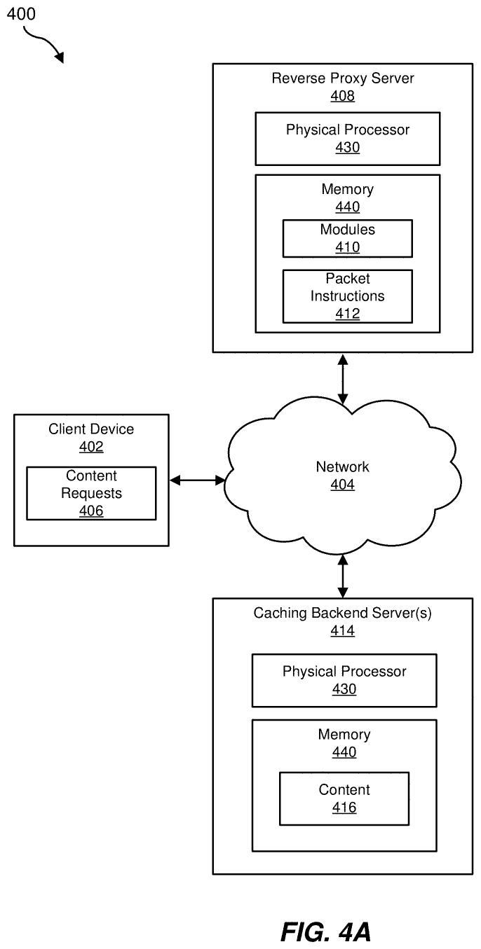

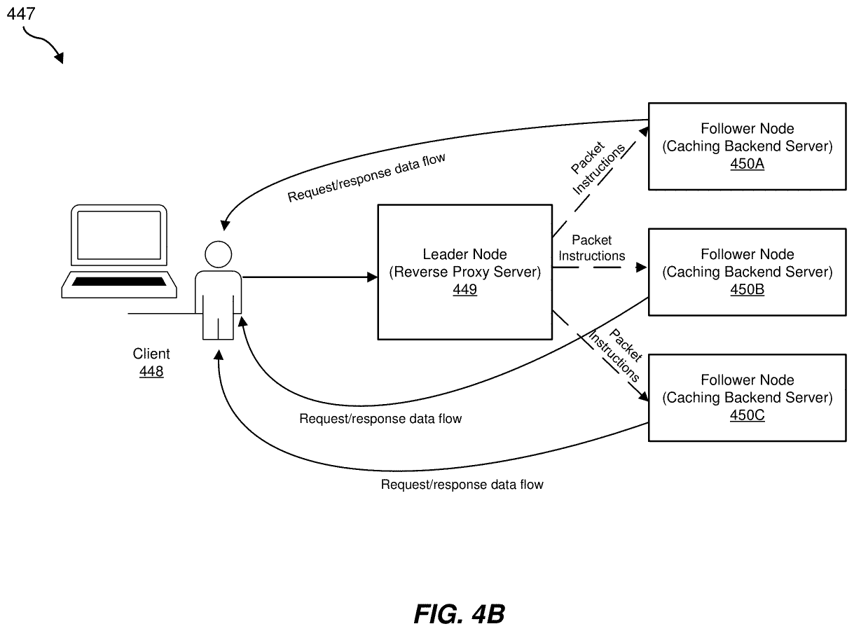

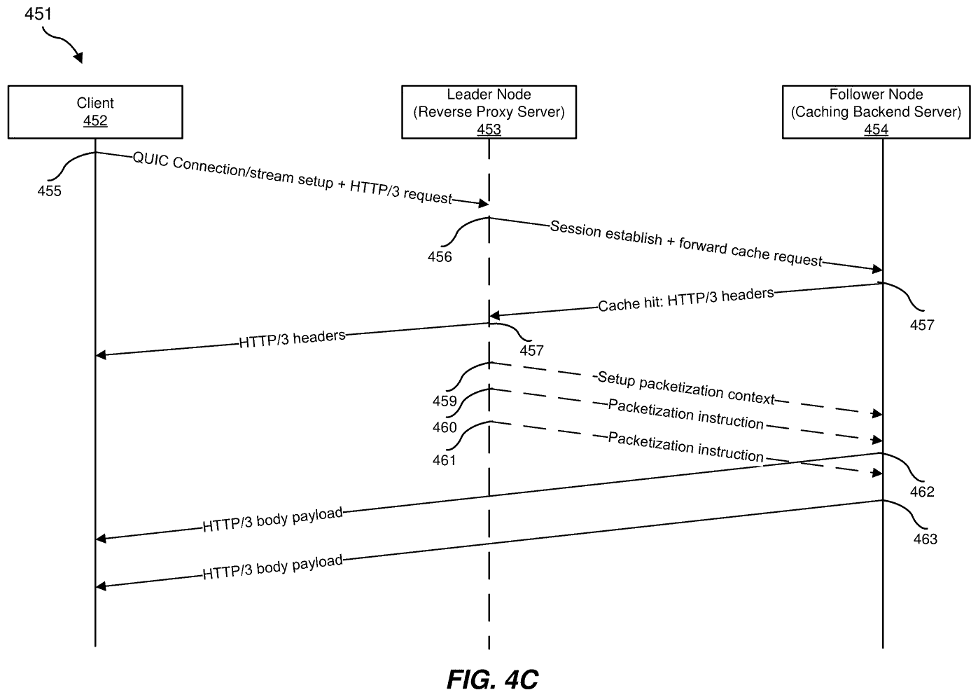

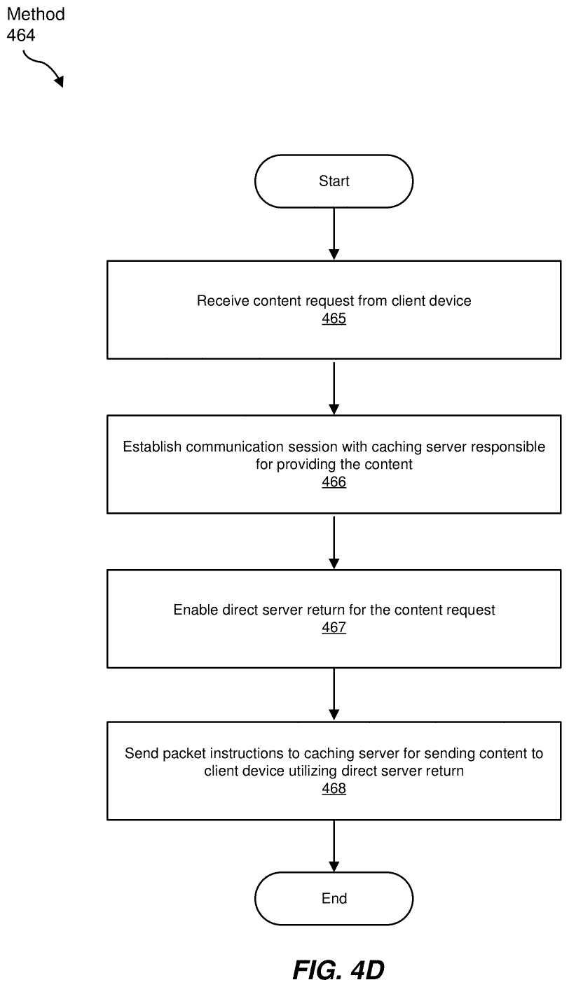

The following will provide, with reference to FIGS. 4A-4B, detailed descriptions of exemplary systems for utilizing direct server return to deliver cached network content. A detailed description of a communication chart for utilizing direct server return to deliver cached network content is provided with reference to FIG. 4C. Detailed descriptions of methods for utilizing direct server return to deliver cached network content are provided with reference to FIG. 4D.

FIG. 4A is a block diagram of an exemplary system 400 for utilizing direct server return to deliver cached network content. As illustrated in this figure, exemplary system 400 may include a client device 402 in communication with a reverse proxy server 408 and one or more caching backend servers 414 via a network 404.

Client device 402 generally represents any type or form of computing device capable of reading computer-executable instructions. In some embodiments, client device 402 may represent an endpoint device that initiates content requests 406 with reverse proxy server 408 for receiving content 416 (e.g., video, images, etc.) from caching backend servers 414. Additional examples of client device 402 include, without limitation, laptops, tablets, desktops, servers, cellular phones, Personal Digital Assistants (PDAs), multimedia players, embedded systems, wearable devices (e.g., smart watches, smart glasses, etc.), smart vehicles, smart packaging (e.g., active or intelligent packaging), gaming consoles, so-called Internet-of-Things devices (e.g., smart appliances, etc.), variations or combinations of one or more of the same, and/or any other suitable computing device.

Reverse proxy server 408 generally represents any type or form of computing device capable of distributing client device content requests (e.g., content requests 406) to caching backend servers 414 for fulfillment at the application layer (e.g., the layer 7 application layer of the open systems interconnection (OSI) model). In some examples, reverse proxy server 408 may be a server in a content delivery network with DSR functionality at the layer 7 application layer. Additional examples of reverse proxy server 408 include, without limitation, security servers, application servers, storage servers, and/or database servers configured to run certain software applications and/or provide various security, web, storage, and/or database services.

Caching backend servers 414 generally represents any type or form of computing device capable of servicing content requests 406 received from reverse proxy server 408 with content 416 in a content delivery network. In some examples, caching backend servers 414 may include multiple individual servers, each storing different cached content in a content delivery network. Additional examples of caching backend servers 414 include, without limitation, security servers, application servers, storage servers, and/or database servers configured to run certain software applications and/or provide various security, web, storage, and/or database services. Although illustrated as a single entity in FIG. 4A, caching backend servers 414 may include and/or represent a plurality of servers that work and/or operate in conjunction with one another.

As illustrated in FIG. 4A, reverse proxy server 408 and caching backend servers 414 may also include one or more memory devices, such as memory 440. In one example, memory 440 of reverse proxy server 408 may store, load, and/or maintain modules 410 and packet instructions 412. Similarly, memory 440 in caching backend servers 414 may store, load, and/or maintain content 416.

As illustrated in FIG. 4A, reverse proxy server 408 and caching backend servers 414 may also include one or more physical processors, such as physical processor 430. In one example, physical processor 430 may execute one or more of modules 410 to facilitate utilizing DSR to deliver cached network content.

Network 404 generally represents any medium or architecture capable of facilitating communication or data transfer. In one example, network 404 may facilitate communication between client device 402, reverse proxy server 408, and caching backend servers 414. In this example, network 404 may facilitate communication or data transfer using wireless and/or wired connections. Examples of network 404 include, without limitation, an intranet, a Wide Area Network (WAN), a Local Area Network (LAN), a Personal Area Network (PAN), the Internet, Power Line Communications (PLC), a cellular network (e.g., a Global System for Mobile Communications (GSM) network), portions of one or more of the same, variations or combinations of one or more of the same, and/or any other suitable network.

FIG. 4B is a block diagram of an exemplary system 447 including a direct server return (DSR) architecture to deliver cached network content. As illustrated in this figure, exemplary system 447 may include a client 448 in communication with a leader node 449 and follower nodes 450A, 450B, and 450C.

In one example, leader node 449 may send packet instructions to one or more of follower nodes 450A, 450B, and/or 450C in response to receiving content requests from client 448. In response, one or more of follower nodes 450A, 4506, and/or 450C may receive the content requests and respond directly to client 448 with the requested content (i.e., via DSR).

In some examples, various connection states between client 448, leader node 449, and follower nodes 450A-450C may be managed using the QUIC transport protocol and HTTP/3 (i.e., HTTP over QUIC). In the QUIC protocol, the entire connection state is managed in the user space. In the event a need arises to transfer state to another host, the transfer may be accomplished utilizing the remote procedure call (RPC) protocol without involving kernel/coordination. Additionally, QUIC provides extensions to negotiate and change the transport behavior between two endpoints thereby facilitating experimentation with new features. Moreover, QUIC utilizes dedicated streams for multiplexed requests. Thus, unlike HTTP/2, where a single TCP stream is shared across multiple requests, HTTP/3 maps different requests to separate QUIC streams that are delivered independently, thereby facilitating the sending of data (e.g., bytes) on different streams from different caching backends. Finally, QUIC encrypts packets individually. Thus, unlike transport layer security (TLS), where a record layer protocol and the entire record (which may be composed of multiple packets) has to be available before decryption, QUIC offers packet level encryption/decryption such that data may be made available as soon as a packet arrives.

For loss detection, QUIC employs both a packet threshold and a time threshold for ACK-based loss detection. In the case of DSR, packets may arrive out of order at the client due to two scenarios: (1) two follower nodes sending packets at the same time such that a larger packet number may arrive before a smaller packet number and (2) leader and follower nodes sending packets at the same time such that a larger packet number from the leader node may arrive before a smaller packet number from the follower node due to an additional delay on the follower node. In the QUIC protocol, packet threshold loss detection may be turned off when DSR is used to account for the fact that packets may inherently be transmitted out of order. Thus, depending on a network setup, time threshold loss detection may need additional tuning to lower its sensitivity if the follower node to client path has a much larger round-trip delay time (RTT) than the leader node to client path. In some examples, QUIC may provide for a sender having more control over a receiver's ACK behavior. For example, QUIC may utilize an “Ignore Order” bit to stop the receiver sending immediate ACKs when packet reordering is observed.

For congestion control, QUIC includes the default New Reno loss-based congestion controller that may be utilized to work with layer 7 (L7) DSR. New Reno signaling (e.g., ACKs and Explicit Congestion Notifications (ECNs)) may be processed on the leader node and congestion control decisions may be made locally. Alternatively, other congestion control algorithms may be used with QUIC and L7 DSR including, for example, the Bottleneck Bandwidth and Round-trip propagation time (BBR) congestion control algorithm developed by GOOGLE, LLC of Mountain View, Calif. BBR, which relies on accurately estimating available bandwidth, utilizes a combination of ACK rate and send rate. Since with L7 DSR, it is technically difficult to estimate the aggregated send rate across multiple follower nodes (even if the follower nodes provide explicit signaling of sent packets back to the leader node), the implementation of BBR may choose to ignore the send rate and rely only on the ACK rate to estimate available bandwidth.

FIG. 4C is a block diagram of a communication chart 451 for utilizing direct server return to deliver cached network content. As illustrated in this figure, communication chart 451 may include a client 452 in communication with a leader node 453 (e.g., a reverse proxy server) and a follower node 454 (e.g., a caching backend server).

In one example, client 452 may send an HTTP/3 request to leader node 453, which may be communicated as a QUIC connection/stream setup+HTTP/3 request 455, for content stored on follower node 454. Leader node 453 may terminate the incoming QUIC connection and maintain associated connection states (e.g., congestion control, flow control, cryptographic connection state (crypto state), etc.). Leader node 453 may also process any and all acknowledgement flags (ACKs) utilized to acknowledge the successful receipt of data packets (i.e., the ACKs are not forwarded to follower node 454).

Upon terminating the incoming QUIC connection, leader node 453 may then receive the content request as an HTTP/3 request. Leader node 453 may then process the HTTP/3 request and compute the follower node (e.g., follower node 454) responsible for serving the requested content. Leader node 453 may then establish a session with follower node 454 and forward the content request as a cache lookup request via session establish+forward cache request 456.

After receiving the cache lookup request from leader node 453, follower node 454 may process the cache lookup request by determining whether the requested content is fully available. If so, follower node 454 may reply to leader node 453 with metadata and cached HTTP response headers via HTTP/3 headers 457 in addition to indicating if the cache lookup request is DSR eligible.

Upon receiving HTTP/3 headers 457 from follower node 454, leader node 453 may forward HTTP/3 headers to client 452 and further determine whether to enable DSR based on: (1) whether the request is DSR eligible as indicated by follower node 454 and (2) other criteria including object size, object popularity, on the fly mutation of the object, etc. Upon determining to enable DSR, leader node 453 may offload an HTTP body transmission to follower node 454. In some examples, the HTTP body transmission may include sending two types of packetization instructions to follower node 454: (1) setup packetization context instructions 459 and packetization instructions 460 and 461. In some examples, setup packetization context instructions 459 may include a one-time setup_context( ) instruction to set up a shared context between leader node 453 and follower node 454. This instruction may include destination information (e.g., IP address, port, and CID), stream identification, encryption information (e.g., AEAD), and header/packet number cipher. In some examples, the same connection/stream/crypto state is shared across multiple send_packet( ) calls. In some examples, setup packetization context instructions 459 may also include multiple send_packets( ) instructions for instructing follower node 454 to send X bytes starting at offset Y with a rate of Z. Additionally, per packet information may also be included (e.g., packet number and stream offset). The rate Z may be used primarily for pacing to avoid network micro-bursts. In some examples, leader node 453 may send send_packets( ) instructions to follower node 454 based on the availability of a send window. As follower node 454 receives the send_packets( ) instructions, it may build, encrypt and transmit QUIC packets (e.g., HTTP/3 body payloads 462 and 463) directly to client 452.

In some examples, errors causing client 452 to disconnect from leader node 453 may be handled as follows: (1) leader node 453 may destruct the established session with follower node 454, (2) if follower node 454 is unresponsive and/or abruptly disconnects the session, leader node 453 may send an H3 RST_STREAM instruction to client 452 so that client 452 may attempt one or more retries, and (3) if the RST_STREAM instruction sent by leader node 453 is unsuccessful, follower node 454 may then choose to terminate the session and clean up the existing state.

FIG. 4D is a flow diagram of an exemplary computer-implemented method 464 for utilizing direct server return for delivery of cached network content. The steps shown in FIG. 4D may be performed by any suitable computer-executable code and/or computing system, including system 400 in FIG. 4A, system 447 in FIG. 4B, and/or variations or combinations of one or more of the same. In one example, each of the steps shown in FIG. 4D may represent an algorithm whose structure includes and/or is represented by multiple sub-steps, examples of which will be provided in greater detail below.

As illustrated in FIG. 4D, at step 465 one or more of the systems described herein may receive a content request from a client device. For example, modules 410 may, as part of reverse proxy server 408 in FIG. 4A, receive one or more content requests 406 from client device 402. In some examples, reverse proxy server 408 may represent a leader node in a content delivery network.

Modules 410 may receive content requests 406 in a variety of ways. In some embodiments, modules 410 may receive a QUIC stream including a hypertext transfer protocol (HTTP) request (e.g., an HTTP/3 request) from client device 402 for content 416 stored on one or more caching backends servers 414. Then, modules 410 may process the HTTP request and determine a caching backend server 414 responsible for providing content 416.

At step 466, one or more of the systems described herein may establish a communication session with the caching server responsible for providing the content requested at step 465. For example, modules 410 may, as part of reverse proxy server 408 in FIG. 4A, establish a communication session with a caching backend server 414 responsible for providing content 416. In some examples, caching backend servers 414 may represent follower nodes in a content delivery network.

Modules 410 may establish the communication session with a caching backend server 414 in a variety of ways. In some embodiments, modules 410 may forward a content request 406 to a caching backend server 414 responsible for providing content 416.

At step 467, one or more of the systems described herein may enable direct server return (DSR) for the content request. For example, modules 410 may, as part of reverse proxy server 408 in FIG. 4A, enable DSR for a content request 406.

Modules 410 may enable DSR in a variety of ways. In some embodiments, modules 410 may enable DSR by: (1) receiving metadata and cached HTTP response headers from a caching backend server 414 and (2) determine, based on the metadata and the cached HTTP response headers, that a content request 406 is DSR eligible. In some examples, modules 410 may enable DSR at the layer 7 (L7) application layer (i.e., L7 DSR).

At step 468, one or more of the systems described herein may send packet instructions to a caching server for sending content to client device utilizing DSR. For example, modules 410 may, as part of reverse proxy server 408 in FIG. 4A, send packet instructions 412 to a caching backend server 414. In one example, packet instructions 412 may include instructions for a caching backend server 414 to send content 416 directly to client device 402 (i.e., utilize DSR to send content 416).

Modules 410 may send packet instructions 412 in a variety of ways. In some embodiments, modules 410 may send an HTTP body transmission including packet instructions 412 to a caching backend server 414. In one example, sending the HTTP body transmission may include sending a group of setup packets containing instructions to setup a shared context between reverse proxy server 408 and a caching backend server 414. The shared context may include destination information, stream identification, encryption information, and header/packet information. Sending the HTTP body transmission may further include sending a group of send packets containing instructions for a caching backend server 414 to transmit QUIC data representing the requested content (i.e., content 416) directly to client device 402.

In conventional content delivery network architectures, content egressed to requesting client devices typically resides in a distributed backend. A reverse proxy is utilized to fetch the content from the caching backend before sending it to the downstream clients. This type of architecture disadvantageously introduces an additional hop and imposes excess overhead (e.g., CPU and network Input/Output) on the reverse proxy to communicate with the caching backend. In some implementations, this excess overhead may represent about twenty percent of the overall processing power on an edge network within a conventional content delivery network. The present disclosure describes utilizing direct server return at the layer 7 application layer (i.e., L7 DSR) to bypass the reverse proxy on the egress path. The caching backend receives lightweight instructions from the reverse proxy and sends content directly to downstream client devices. By utilizing DSR, increased efficiency in the serving large amounts content is realized and overall network capacity is increased without physically provisioning additional servers. The present disclosure further describes utilizing DSR by leveraging HTTP/3 and QUIC, which is usually implemented in user space, to allow for passing packetization instructions from the reverse proxy to the caching backend. The reverse proxy (also known as a leader rode) may be utilized to terminate requests, coordinate, and possibly synchronize connection state with a caching backend (also known as follower node). All state management and decision making is performed on the leader node which utilizes a simple messaging scheme to inform the follower nodes when it wishes to send packets containing content stored on the follower node. Isolating the state to the leader node simplifies the amount of coordination required between the nodes. A small amount of initial setup coordination may be required up to determine if a requested resource may be effectively be sent by the follower node. Content delivery networks, as well as other storage services, may benefit from utilizing L7 DSR to reduce operational costs associated with sending data to users.

### Example Embodiments

### Example 12

A computer-implemented method comprising (i) receiving, by a reverse proxy server, a content request from a client device, (ii) establishing, by the reverse proxy server, a communication session with a caching server responsible for providing the content, (iii) enabling, by the reverse proxy server, direct server return (DSR) for the content request, and (iv) sending, by the reverse proxy server, packet instructions to the caching server for directly sending the content to the client device utilizing the DSR, wherein utilizing the DSR reduces a processing overhead associated with communications between the reverse proxy server and the caching server for providing the content to the client device.

### Example 13

The method of example 12, wherein receiving the content request from the client device comprises receiving a QUIC stream including a hypertext transfer protocol (HTTP) request for the content, processing the HTTP request, and determining the caching server, from among a plurality of network nodes, responsible for providing the content.

### Example 14

The method of examples 12 and 13, wherein establishing the communication session with the caching server comprises forwarding the content request from the client device to the caching server.

### Example 15

The method of any of examples 12-14, wherein enabling the DSR for the content request comprises receiving metadata and cached HTTP response headers from the caching server and determining, based on the metadata and the cached HTTP response headers that the content request is eligible for the DSR.

### Example 16

The method of any of examples 12-14, wherein enabling the DSR enabling comprises enabling the DSR at the layer 7 application layer.

### Example 17

The method of any of examples 12-15, wherein sending the packet instructions to the caching server for directly sending the content to the client device utilizing DSR comprises sending an HTTP body transmission comprising the packet instructions to the caching server.

### Example 18

The method of any of examples 12-15, wherein sending the HTTP body transmission comprises sending a group of setup packets containing instructions to setup a shared context between the reverse proxy server and the caching server, wherein the shared context comprises destination information, stream identification, encryption information, and header/packet information and sending a group of send packets containing instructions for the caching server to transmit QUIC data representing the requested content directly to the client device.

### Example 19

The method of any of examples 12-18, wherein the reverse proxy server comprises a leader node in a content delivery network.

### Example 20

The method of any of examples 12-19, wherein the caching server comprises a follower node in a content delivery network.

Apparatus, System, and Method for Managing and Securing High-Power Medusa Cable to Chassis

Medusa cables are often used in IT equipment, such as data centers, for delivering power from a rack to a chassis. Cable management may be critical to prevent damage to such medusa cables. A damages medusa cable may cause catastrophic failures to equipment by shorting an entire chassis and may additionally present safety risks to technicians. For example, a medusa cable that is not properly secured may be susceptible to being shifted to an unsafe location, such as near a metal bracket in a chassis. If a nearby HDD drawer is slid out, the medusa cable may get sheared open, exposing a technician to possible electrical shock.

To accommodate medusa cable failures, medusa cables may be designed to be field replaceable units (“FRU”). Traditionally, medusa cables are managed and secured to the chassis via Velcro straps. However, Velcro straps may not effectively hold medusa cables in place because medusa cables generally lack any mechanical features for mounting purposes and may likely slide through the straps. In addition, because medusa cables lack any indications of possible mounting positions, human error may be inevitable during the factory assembly process.

The present disclosure is generally directed to cable management. As will be explained in greater detail below, embodiments of the present disclosure may provide a grommet for holding cables and a corresponding clip, mountable onto a chassis, for holding the grommet. The grommet and clip arrangement may allow for a more fool-proof assembly process to prevent safety issues due to poor cable management, without sacrificing serviceability of the cables.

Features from any of the embodiments described herein may be used in combination with one another in accordance with the general principles described herein. These and other embodiments, features, and advantages will be more fully understood upon reading the following detailed description in conjunction with the accompanying drawings and claims.

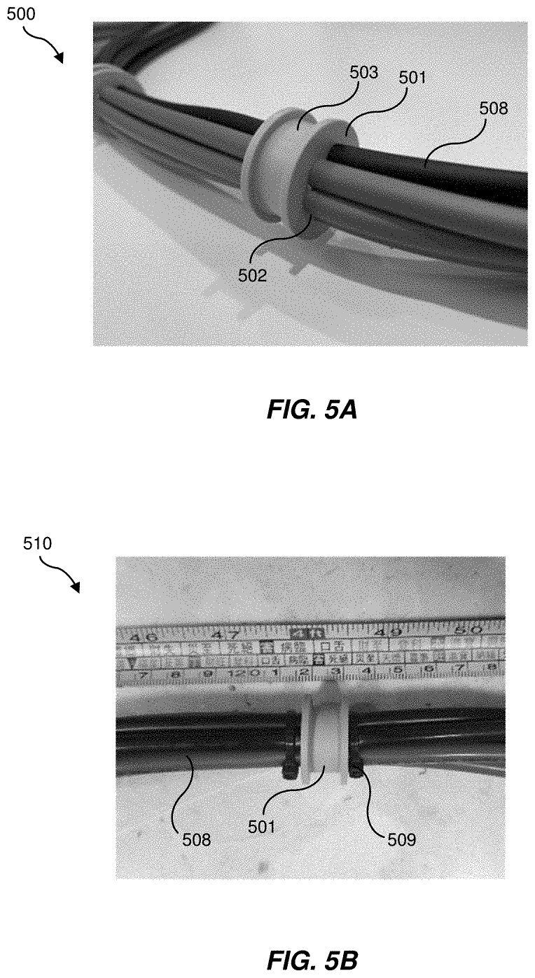

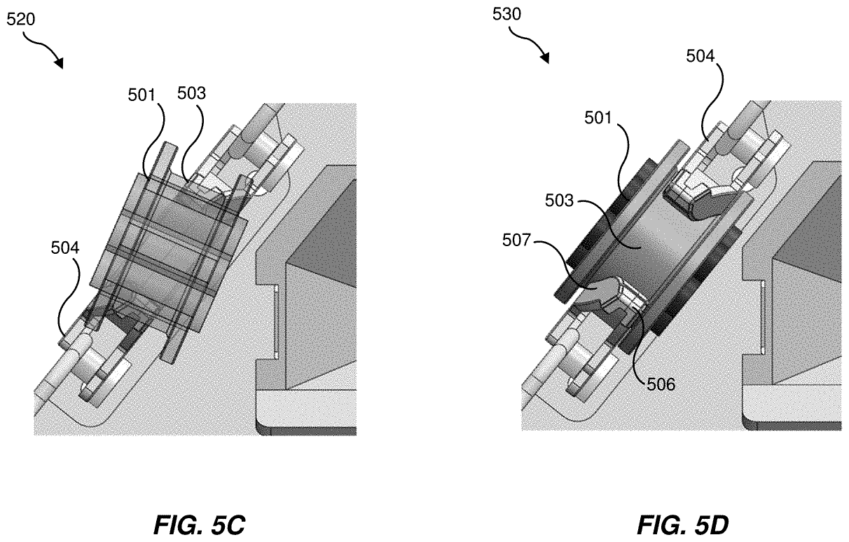

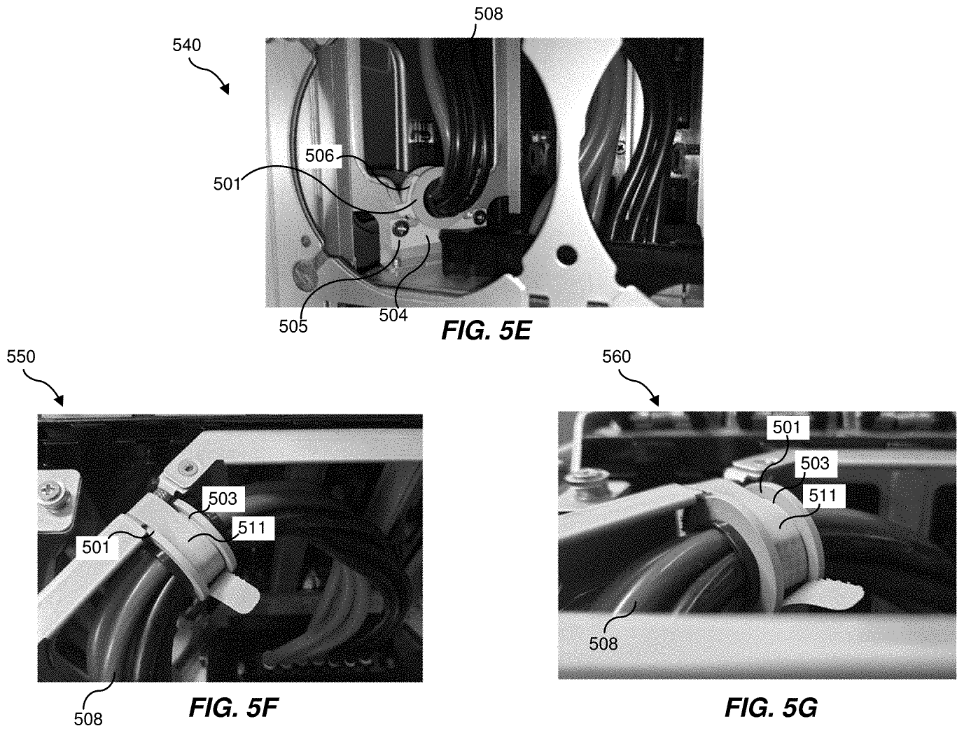

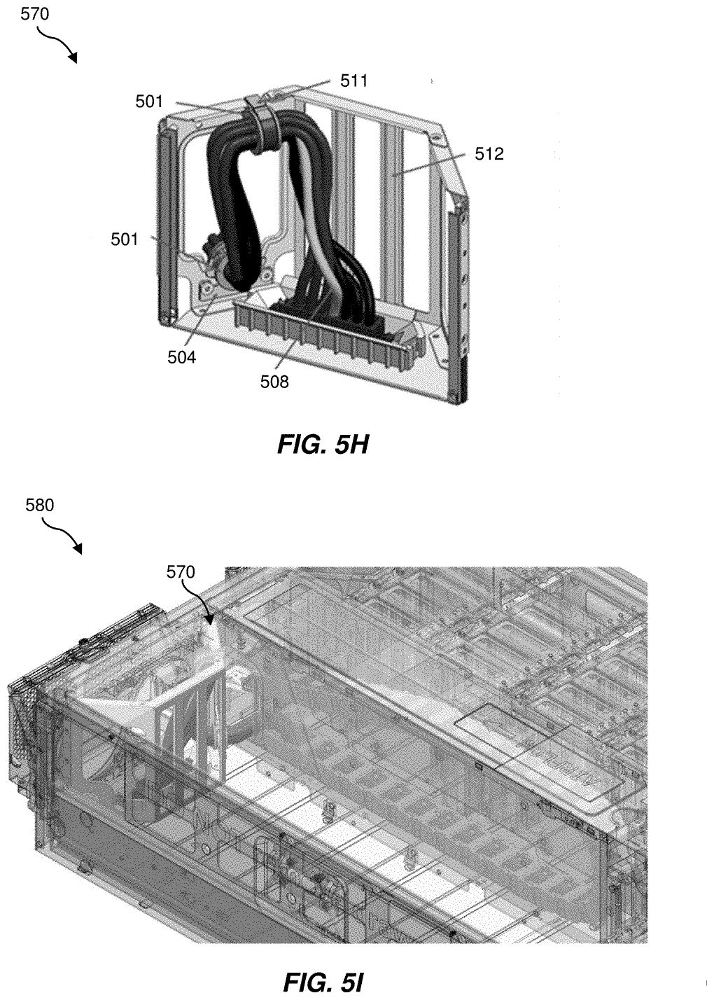

FIG. 5A illustrates an apparatus 500 including a grommet 501 and a medusa cable 508. Grommet 501 may include an opening 502 shaped to hold medusa cable 508 and a groove 503 around an outer diameter of grommet 501 as will be described further below. As seen in FIG. 5A, opening 502 may be shaped to fit around medusa cable 508 without significant gaps between grommet 501 and medusa cable 508. Medusa cable 508 may include various cables that may join, at one or both ends, into a single plug. Although the examples herein are described with respect to medusa cables, in other examples, the cables may include one or more cables of uniform or non-uniform shapes and/or diameters.

Grommet 501 may made of a resilient material, such as plastic, rubber, etc. Grommet 501 may be mounted onto medusa cable 508 by over-molding grommet 501 onto medusa cable 508. Alternatively or in addition, grommet 501 may be assembled or otherwise fit around medusa cable 508 and further held in place with straps or other retaining mechanism at one or both ends of grommet 501. FIG. 5B illustrates an apparatus 510 in which grommet 501 may be secured to medusa cable 508 using a zip tie 509 on both ends of grommet 501.

FIG. 5C illustrates an apparatus 520 including grommet 501 and a clip 504 for holding grommet 501. Clip 504 may mate with grommet 501, and more specifically with groove 503. Clip 504 may be designed to snap onto grommet 501 and provide sufficient retention force such that grommet 501 may not be dislodged from clip 504 from shocks and vibrations. In addition, a clip-in force and a pull-out force for retaining and removing grommet 501 from clip 504 may be designed within an ergonomic comfort specification for pushing and pulling. As such, a technician may be able to insert and/or dislodge grommet 501 from clip 504 using human force and without requiring a tool.

FIG. 5D illustrates an apparatus 530 including grommet 501 and clip 504 having an extension 506 with a redirecting feature 507. As illustrated in FIG. 5D, clip 504 may have two extensions 506 configured to fit into groove 503 around the outer diameter and at least partially surround grommet 501. Extension 506 may include redirecting feature 507, which may be a ramped or otherwise angled surface, to allow mating with grommet 501, and in particular groove 503, at an offset angle. Due to a natural cable bending radius of medusa cable 508, grommet 501 may not be easily aligned with clip 504. For instance, FIG. 5C illustrates how grommet 501 may initially contact clip 504 at an offset angle. Redirecting feature 507 may guide grommet 501 into correct alignment as grommet 501 interfaces with clip 504, as illustrated in FIG. 5D.

FIG. 5E illustrates an apparatus 540 including grommet 501, clip 504, and medusa cable 508 installed inside a chassis. Grommet 501, secured to medusa cable 508, may be held by clip 504 via extension 506. Clip 504 may include a base 505 for mounting onto the chassis surface, such as a bracket or frame extending from the chassis surface. As illustrated in FIG. 5E, base 505 may be mounted by screws, although in other examples, other suitable mounting mechanisms may be used. As further illustrated in FIG. 5E, extension 506 may extend from base 505.

In some examples, a chassis surface may not provide a suitable location for mounting clip 504. For instance, medusa cable 508 may require placement along inner portions of the chassis that may not have sufficient space or mountable surface for clip 504. FIG. 5F illustrates an apparatus 550 including grommet 501, medusa cable 508, and a strap 511. FIG. 5G illustrates an apparatus 560 which may correspond to apparatus 550 illustrated from another view.

As illustrated in FIGS. 5F and 5G, rather than securing grommet 501 to the chassis using clip 504, strap 511 may be looped around grommet 501, specifically groove 503, as well as a frame within the chassis. In some examples, strap 511 may be a dual-color Velcro strap having a first color (e.g., green) and a second color (e.g., black). If strap 511 is sufficiently tightened, an end of strap 511 may pass a boundary line between the first and second colors such that the second color may not be exposed. However, if strap 511 is not sufficiently tight, the second color may be exposed.

FIG. 5H illustrates a chassis sub-assembly 570. A first grommet 501 may secure medusa cable 508 to a chassis bracket 512 via strap 511. A second grommet 501 may secure medusa cable 508 via clip 504 mounted to chassis bracket 512. FIG. 5I illustrates a chassis 580 and chassis sub-assembly 570 within chassis 580.

As described herein, embodiments of the present disclosure include a grommet that may be manufactured to a specific portion of a cable, such as a medusa cable. The grommet may be secured to a chassis using a clip that may be mounted to the chassis. If a mounting position for the clip is unavailable, the grommet may be directly secured to the chassis, for example using a strap to secure the grommet to a chassis bracket. This design may provide a fool-proof feature for managing, routing, and securing cables while preserving serviceability to prevent safety incidents due to cable mismanagement.

### Example Embodiments

### Example 21

An apparatus comprising: a grommet comprising: an opening shaped to hold at least one cable; and a groove around an outer diameter of the grommet; and a clip comprising: a base portion; and at least one extension extending from the base portion and configured to mate with the groove.

### Example 22

The apparatus of example 21, wherein the at least one extension comprises a redirecting feature to allow mating with the groove at an offset angle.

### Example 23

The apparatus of example 22, wherein the redirecting feature comprises a ramped surface.

### Example 24

The apparatus of any of examples 21-23, wherein the at least one extension comprises a plurality of extensions configured to fit into the groove and at least partially surround the grommet.

### Example 25

The apparatus of any of examples 21-24, wherein the base portion is mountable onto a surface.

### Example 26

The apparatus of any of examples 21-25, wherein the opening is shaped to fit around the at least one cable.

### Example 27

The apparatus of any of examples 21-26, wherein the at least one cable comprises a medusa cable.

Apparatus, System, and Method for Organizationally Distributing Cables to Rackmount Network Devices

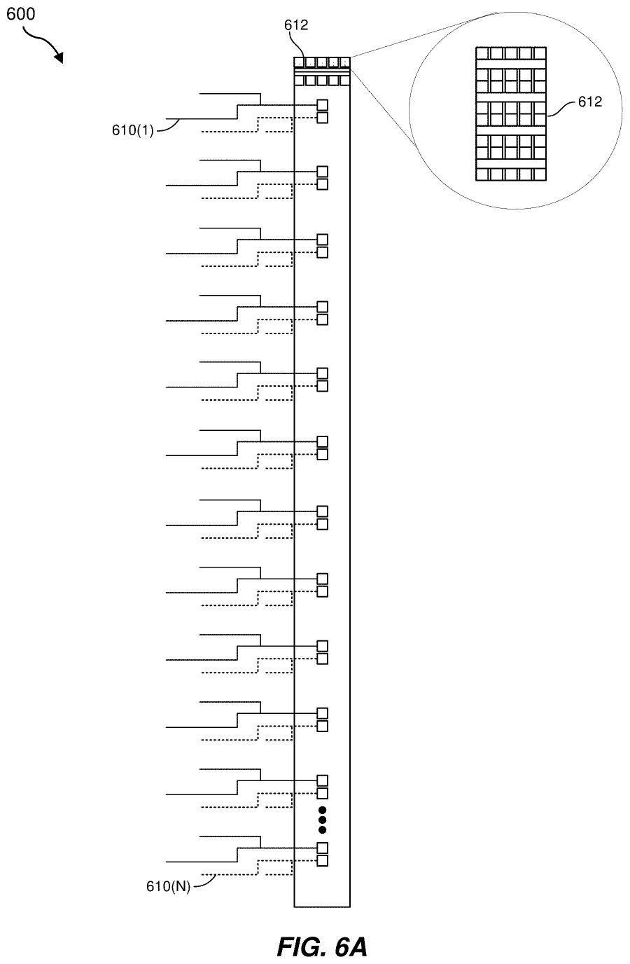

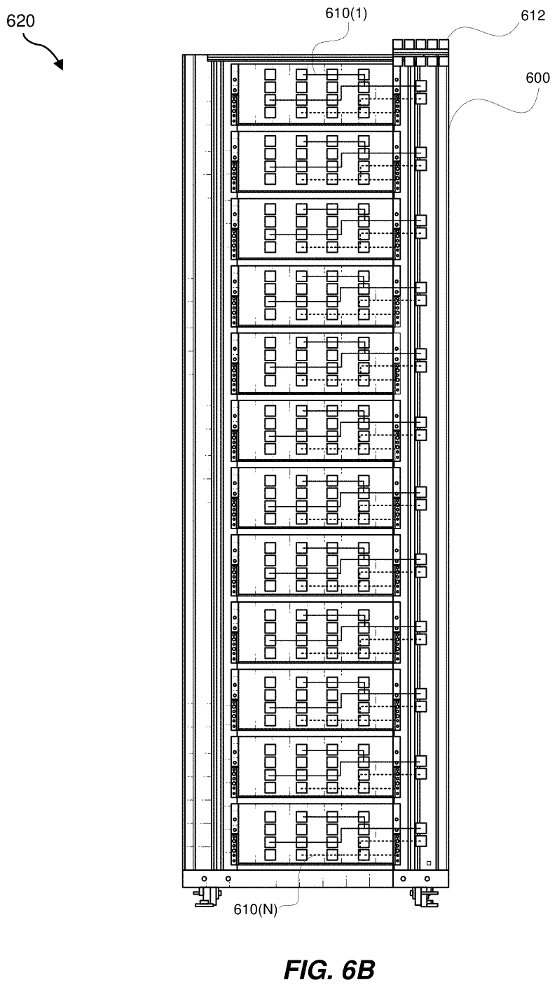

The present disclosure involves apparatuses, systems, and methods for organizationally distributing cables to rackmount network devices. For example, a cable distribution box (e.g., cable distribution box 600 in FIG. 6A) may be coupled to a network and/or server rack (e.g., rack 620 in FIG. 6B). In this example, the cable distribution box may include and/or represent a conduit and/or enclosure that runs and/or extends across, down, or through one side of the rack.

This cable distribution box may include and/or contain a modular connector landing (e.g., modular connector landing 612 in FIG. 6A) coupled to a top panel of the cable distribution box. In this example, the cable distribution box may include and/or contain a set of connection ports disposed across a front panel of the cable distribution box. The distribution box may also include and/or contain a set of communication channels and/or signals (e.g., fiber optics and/or conductors) communicatively coupled between the modular connector landing and the set of connection ports. In one example, a set of cables (e.g., fiber optic cables 610(1)-(N) in FIG. 6A) may communicatively couple the set of rackmount network devices housed in the rack to the set of connection ports disposed across the front panel of the cable distribution box.

The various apparatuses and systems described herein may organize, house, and/or guide cables that facilitate communication with rackmount network devices. By doing so, these apparatuses and systems may enable such cables to avoid unintentional knotting and/or clustering (in, e.g., a so-called “rat's nest”) that sometimes result from handling by technicians and/or administrators. Accordingly, these apparatuses and/or systems may be able to improve access to the rackmount network devices and/or other rackmount components, thereby performing maintenance and/or replacement of such devices and/or components easier for technicians and/or administrators. These apparatuses and/or systems may, therefore, constitute and/or represent an effective cable management solution for the corresponding network and/or server rack.

In some examples, a Mobile Core Rack (MCR) may house, store, and/or include a variety of rackmount network devices. In one example, the MCR may include and/or provide various slots that are each fitted and/or dimensioned to accept and/or house a rackmount network device. Additionally or alternatively, such rackmount network devices may include and/or represent Field-Replaceable Units (FRUs) capable of being replaced and/or accessed for maintenance by technicians and/or administrators. Additional examples of such rackmount network devices include, without limitation, Physical Interface Cards (PICS), Flexible PIC Concentrators (FPCs), Switch Interface Boards (SIBS), linecards, control boards, routing engines, communication ports, fan trays, connector interface panels, servers, network devices or interfaces, routers, optical modules, service modules, rackmount computers, portions of one or more of the same, variations or combinations of one or more of the same, and/or any other suitable devices.

In some examples, a cable distribution box may be physically coupled and/or attached to the MCR. In one example, the cable distribution box may include and/or represent a fiber optic housing and/or storage unit that is coupled and/or attached to the MCR. In this example, the cable distribution box may include and/or incorporate a front panel on which various connection ports that are disposed for access and/or connection to various electrical and/or communication signals. Examples of such connection ports include, without limitation, Modular Type Package (MTP) ports, Quad Small Form-factor Pluggable (QSFP) ports, Ethernet ports, fiber optic ports, Fibre Channel ports, optical ports, InfiniBand ports, CXP connectors, Multiple-Fiber Push-On/Pull-Off (MPO) connectors, XAUI ports, XFP transceivers, XFI interfaces, C Form-factor Pluggable (CFP) transceivers, variations of one or more of the same, combinations of one or more of the same, or any other suitable communication ports.

In some examples, the cable distribution box may house, store, and/or include various conductors, wires, cables, and/or fiber optics that run from the front panel to a modular connector landing for access by technicians and/or administrators. In one example, this modular connector landing may include and/or represent an MTP connector landing coupled to, attached to, and/or incorporated in a top panel of the cable distribution box. In this example, the MTP connector landing may include and/or represent a connection or access point for certain communication cabling and/or fiber optics that ultimately terminate at and/or reach the rackmount network devices. For example, the MTP connector landing may include and/or incorporate various connection ports (e.g., any of those described above in connection with the front panel) that are disposed atop the cable distribution box for access and/or connection to various electrical and/or communication signals.

In some examples, various communication cables may be communicatively coupled and/or attached between the set of connection ports disposed across the front panel of the cable distribution box and the set of rackmount network devices housed in the rack. For example, one side of each communication cable may be inserted into a connection port disposed on the front panel of the cable distribution box, and another side of each communication cable may be inserted into a corresponding connection port disposed on one of the rackmount network devices housed in the MCR. Examples of communication cables include, without limitation, MTP cables, Lucent Connector (LC/DX) cables, patch cables, QSFP cables, Ethernet cables, fiber optic cables, Fibre Channel cables, optical cables, InfiniBand cables, CXP cables, MPO cables, XAUI cables, XFP cables, XFI cables, CFP cables, variations of one or more of the same, combinations of one or more of the same, or any other suitable communication cables.

In one example, a rack-mounted fiber distribution box known as a “B-Box” may include and/or represent a fiber optics housing associated with and/or communicatively coupled to a MTP connector landing and/or panel located at the top of an MCR. In this example, the “B-Box” may be incorporated into a side allocated to and/or reserved for a Vertical Cable Manager (VCM) of the MCR. On the front, this “B-Box” may bundle LC/DX cables at ports located at the landing of each network device. Each MTP panel at the top of the MCR may be mapped to an LC/DX cable bundled on the front of the “B-Box” in accordance with a particular configuration (e.g., a service provider's network architecture).

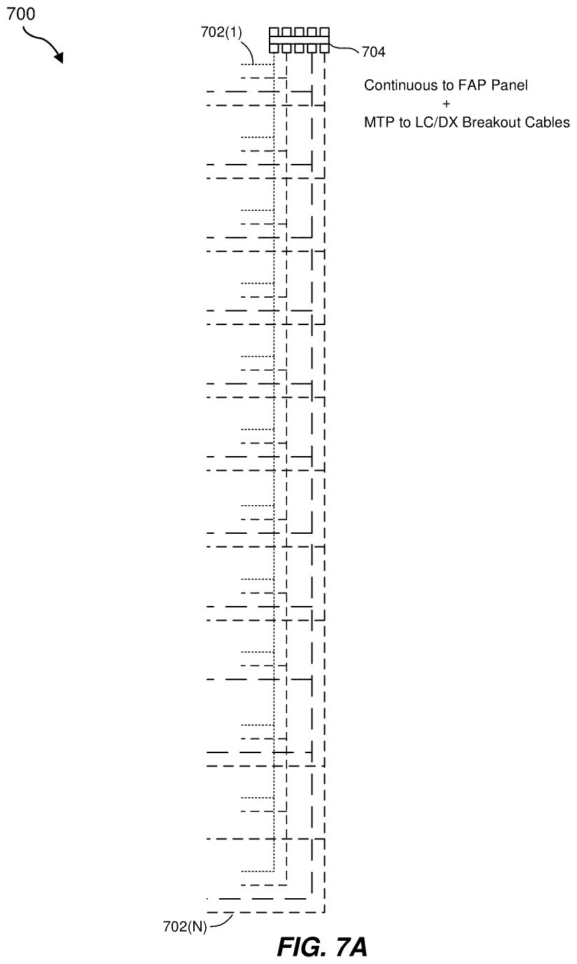

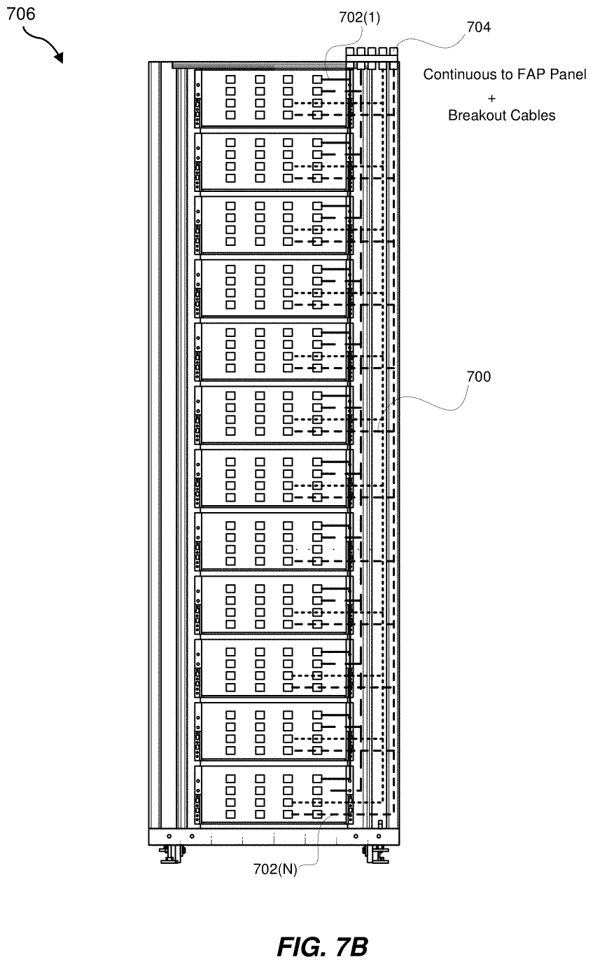

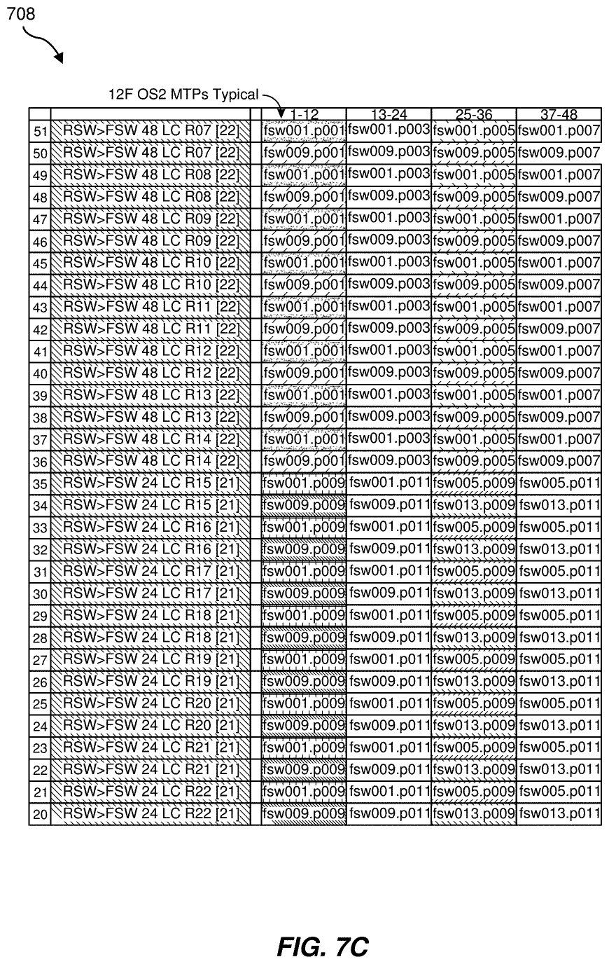

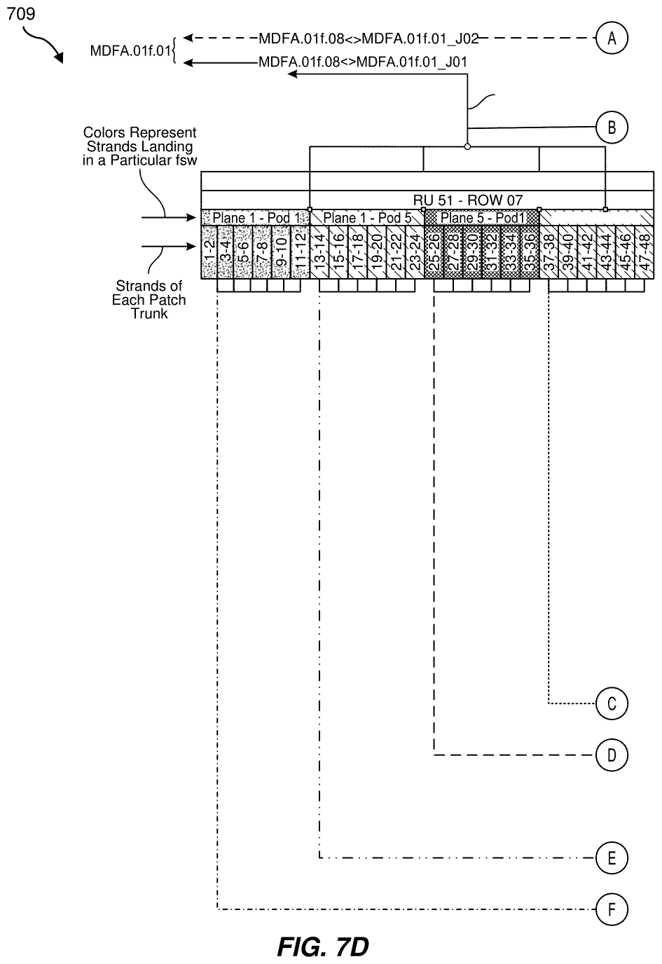

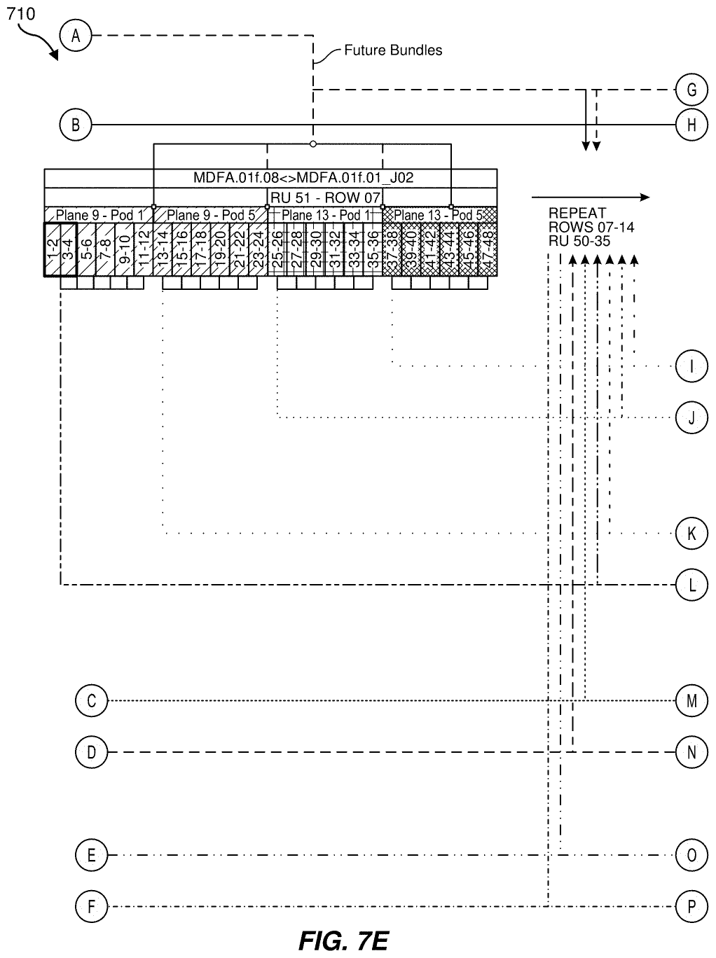

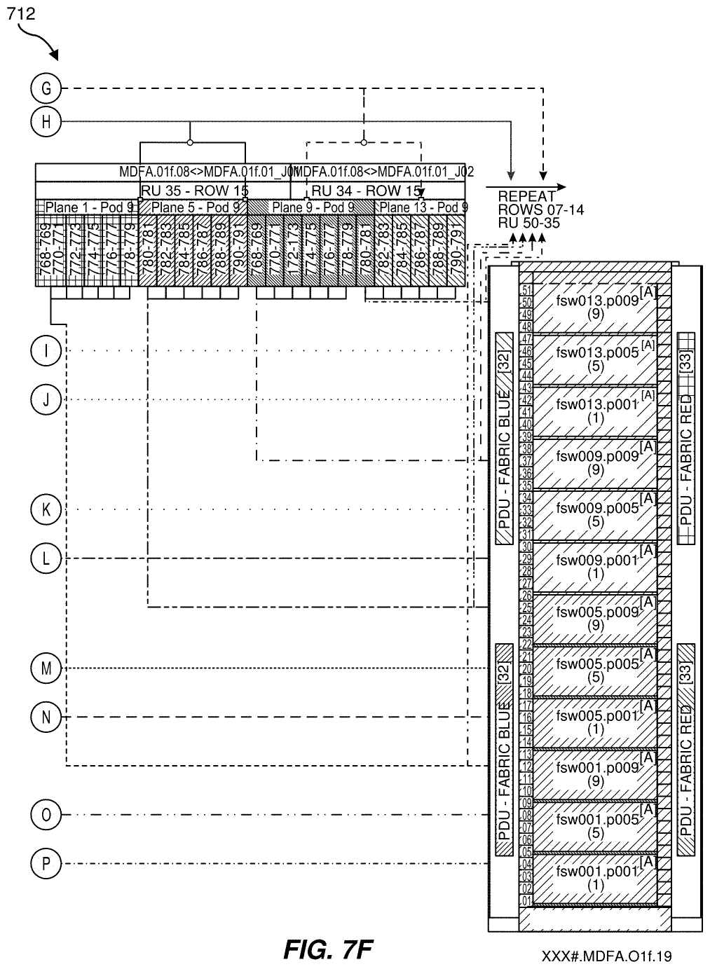

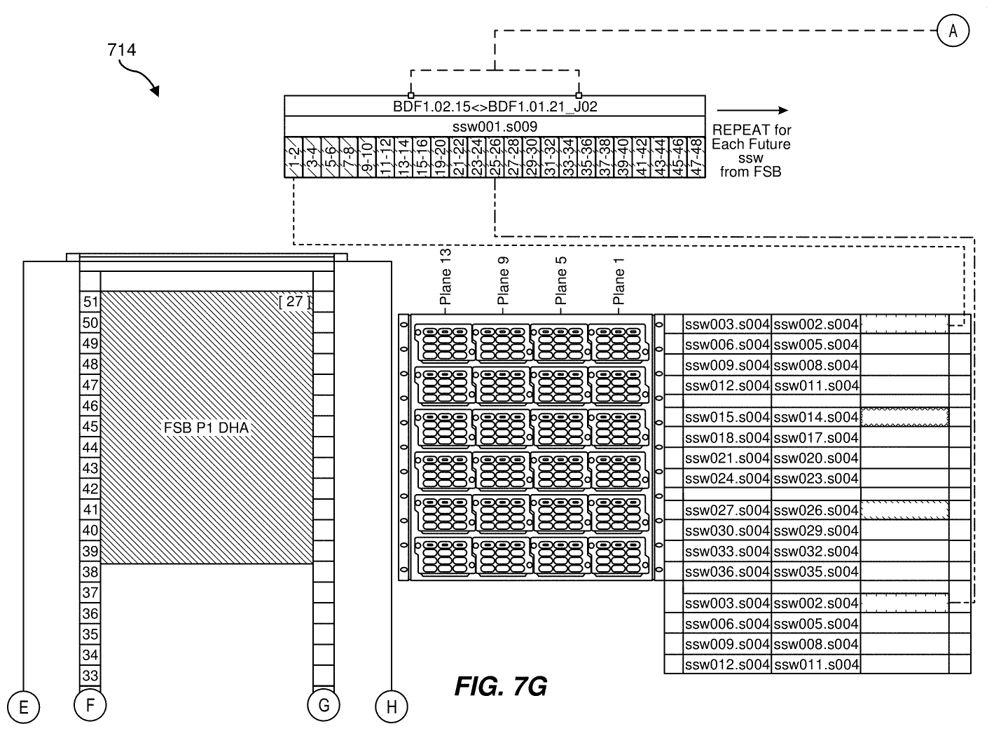

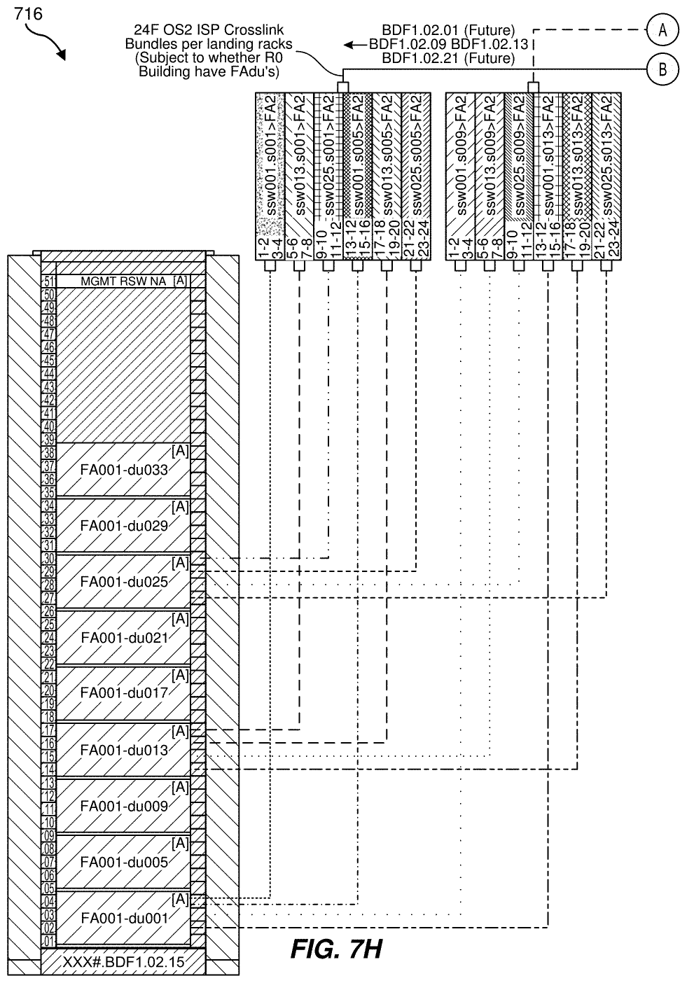

In one example, a vertical cable manager (e.g., vertical cable manager 700 in FIG. 7A) may be coupled to one side of a network and/or server rack (e.g., rack 706 in FIG. 7B) that houses a set of rackmount network devices. In this example, the vertical cable manager may include and/or represent a conduit and/or partial enclosure that runs and/or extends across, down, or through one side of the rack.

In some examples, a cable breakout panel (e.g., cable breakout panel 704 in FIG. 7A) may be coupled to the vertical cable manager. In such examples, the cable breakout panel may include and/or represent a modular connector landing that is coupled to the top of the vertical cable manager. Additionally or alternatively, the cable breakout panel may include and/or represent a set of connection ports that are each fitted to accept a communication cable. Accordingly, the cable breakout panel may constitute and/or represent an interface at which multiple cables are communicatively coupled together and/or to other internal or external networking signals. In one example, a set of cables (e.g., fiber optic cables 702(1)-(N) in FIG. 7A) may communicatively couple the set of rackmount network devices housed in the rack to the set of connection ports included in the cable breakout panel.

In some examples, a cable breakout panel may be physically coupled and/or attached to a vertical cable manager incorporated into and/or coupled to the MCR. In one example, the cable breakout panel may include and/or represent a fiber optic housing and/or interface unit that is coupled and/or attached to the vertical cable manager of the MCR. In this example, the cable breakout panel may be coupled and/or attached to the top side of the vertical cable manager to facilitate access to various connection ports and/or cable connection points for manually patching cables to the rackmount network devices housed by the MCR. Examples of such connection ports include any of those mentioned in the present disclosure.

In some examples, the cable breakout panel may house, store, and/or include various conductors, wires, cables, and/or fiber optics that run from the top side of the vertical cable manager to the rackmount network devices for access by technicians and/or administrators. In one example, this cable breakout panel may include and/or represent an MTP connector landing coupled to, attached to, and/or incorporated in a top panel of the vertical cable manager. In this example, the MTP connector landing may include and/or represent a connection or access point for certain communication cabling and/or fiber optics that ultimately terminate at and/or reach the rackmount network devices. For example, the MTP connector landing may include and/or incorporate various connection ports (e.g., any of those mentioned in the present disclosure) that are disposed atop the vertical cable manager for access and/or connection to various electrical and/or communication signals.

In some examples, various communication cables may be communicatively coupled and/or attached between the set of connection ports disposed across the cable breakout panel and the set of rackmount network devices housed in the rack. For example, one side of each communication cable may be inserted into a connection port disposed on the cable breakout panel, and another side of each communication cable may be inserted into a corresponding connection port disposed on one of the rackmount network devices housed in the MCR. Examples of communication cables include, without limitation, MTP cables, Lucent Connector (LC/DX) cables, patch cables, QSFP cables, Ethernet cables, fiber optic cables, Fibre Channel cables, optical cables, InfiniBand cables, CXP cables, MPO cables, XAUI cables, XFP cables, XFI cables, CFP cables, variations of one or more of the same, combinations of one or more of the same, or any other suitable communication cables.

In one example, a rack-mounted continuous fiber adapter panel with LC/DX breakout cables may be installed on and/or couple to a side panel and/or vertical cable manager of an MCR. Accordingly, a rack-mounted continuous fiber adapter panel may be mounted at the top of the MCR. This rack-mounted continuous fiber adapter panel may effectively divide its associated cabling into individual LC/DX fiber optic cables in a fan-out arrangement. These LC/DX fiber optic cables may reach and/or be connected to corresponding network switches housed in the MCR. The rack-mounted continuous fiber adapter panel and the LC/DX fan-out arrangement may be optimized for a particular purpose.

In some examples, the apparatuses and systems described herein may facilitate organizationally distributing cables to rackmount network devices. In such examples, these apparatuses and systems may incorporate various port arrangements and/or configurations that call for organizationally distributing cables to rackmount network devices. For example, exemplary port arrangement 708 in FIG. 7C, exemplary port arrangement 709 in FIG. 7D, and/or exemplary port arrangement 710 in FIG. 7E may exhibit and/or demonstrate a certain degree of complexity that is potentially mitigated and/or overcome by one or more of the cable management solutions described above in connection with FIGS. 6A, 6B, 7A, and 7B. Additionally or alternatively, exemplary system 712 in FIG. 7F, exemplary system 714 in FIG. 7G, and/or exemplary system 716 in FIG. 7H may incorporate and/or apply one or more of the cable management solutions described above in connection with FIGS. 6A, 6B, 7A, and 7B.

### Example Embodiments

### Example 28

An apparatus comprising: a rack that houses a plurality of rackmount network devices and a cable distribution box coupled to the rack, wherein the cable distribution box comprises a modular connector landing coupled to a top panel of the cable distribution box, a plurality of connection ports disposed across a front panel of the cable distribution box, a plurality of communication channels communicatively coupled between the modular connector landing and the plurality of connection ports, and a plurality of cables communicatively coupled between the plurality of connection ports and the plurality of rackmount network devices housed in the rack.

### Example 29

An apparatus comprising: a rack that houses a plurality of rackmount network devices, a vertical cable manager coupled to a side of the rack, and a cable breakout panel coupled to the vertical cable manager, wherein the cable breakout panel comprises a modular connector landing coupled to a top of the vertical cable manager, a plurality of connection ports that are each fitted to accept a communication cable, and a plurality of cables communicatively coupled between the plurality of connection ports and the plurality of rackmount network devices housed in the rack.

As detailed above, the computing devices and systems described and/or illustrated herein broadly represent any type or form of computing device or system capable of executing computer-readable instructions, such as those contained within the modules described herein. In their most basic configuration, these computing device(s) may each include at least one memory device and at least one physical processor.

In some examples, the term “memory device” generally refers to any type or form of volatile or non-volatile storage device or medium capable of storing data and/or computer-readable instructions. In one example, a memory device may store, load, and/or maintain one or more of the modules described herein. Examples of memory devices include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

In some examples, the term “physical processor” generally refers to any type or form of hardware-implemented processing unit capable of interpreting and/or executing computer-readable instructions. In one example, a physical processor may access and/or modify one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), portions of one or more of the same, variations or combinations of one or more of the same, or any other suitable physical processor.

Although illustrated as separate elements, the modules described and/or illustrated herein may represent portions of a single module or application. In addition, in certain embodiments one or more of these modules may represent one or more software applications or programs that, when executed by a computing device, may cause the computing device to perform one or more tasks. For example, one or more of the modules described and/or illustrated herein may represent modules stored and configured to run on one or more of the computing devices or systems described and/or illustrated herein. One or more of these modules may also represent all or portions of one or more special-purpose computers configured to perform one or more tasks.

In addition, one or more of the modules described herein may transform data, physical devices, and/or representations of physical devices from one form to another. Additionally or alternatively, one or more of the modules recited herein may transform a processor, volatile memory, non-volatile memory, and/or any other portion of a physical computing device from one form to another by executing on the computing device, storing data on the computing device, and/or otherwise interacting with the computing device.

In some embodiments, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A system comprising at least one of:
a network device comprising:
a primary network interface controller comprising a master physical clock for receiving precision time protocol (PTP) signals;
a plurality of secondary network interface controllers, each of the secondary network interface controllers comprising an additional physical clock for receiving the PTP signals;
a network namespace associated with the primary network interface controller;
an additional network namespace associated with each of the secondary network interface controllers;
at least one network interface utilized for synchronizing the PTP signals between the master physical clock in the primary network interface controller and the additional physical clocks in each of the secondary network interface controllers; and
at least one physical processor that determines an accuracy measurement of PTP timing synchronization between the master physical clock in the primary network interface controller and each of the additional physical clocks in the secondary network interface controllers by executing the network namespace and the additional network namespaces;
a grommet apparatus comprising:
a grommet comprising:
an opening shaped to hold at least one cable; and
a groove around an outer diameter of the grommet; and
a clip comprising:
a base portion; and
at least one extension extending from the base portion and configured to mate with the groove;
a rack apparatus comprising:
a rack that houses a plurality of rackmount network devices and a cable distribution box coupled to the rack, wherein the cable distribution box comprises a modular connector landing coupled to a top panel of the cable distribution box;
a plurality of connection ports disposed across a front panel of the cable distribution box;
a plurality of communication channels communicatively coupled between the modular connector landing and the plurality of connection ports; and
a plurality of cables communicatively coupled between the plurality of connection ports and the plurality of rackmount network devices housed in the rack; or
an additional rack apparatus comprising:
an additional rack that houses a plurality of additional rackmount network devices, a vertical cable manager coupled to a side of the additional rack, and a cable breakout panel coupled to the vertical cable manager, wherein the cable breakout panel comprises a modular connector landing coupled to a top of the vertical cable manager;
a plurality of connection ports that are each fitted to accept a communication cable; and
a plurality of additional cables communicatively coupled between the plurality of connection ports and the plurality of additional rackmount network devices housed in the additional rack.

2. The network device of claim 1, wherein the network namespace and the additional network namespaces are executed utilizing one or more master physical clock threads to simulate a plurality of PTP-enabled hops from the master physical clock to at least one of the additional physical clocks.

3. The network device of claim 2, wherein the at least one of the additional physical clocks comprises a boundary clock.

4. The network device of claim 1, wherein the accuracy measurement of the PTP timing synchronization is determined by:
generating one or more PTP queries for the master physical clock and each of the additional physical clocks; and
timestamping the PTP queries.

5. The network device of claim 1, wherein the network namespace associated with the primary network interface controller isolates the primary network interface controller from the network namespace associated with each of the secondary network interface controllers.

6. The network device of claim 1, wherein the network namespace associated with each of the secondary network interface controllers isolates each of the secondary network interface controllers from each other.

7. The network device of claim 1, wherein at least one of the additional physical clocks comprises an ordinary clock.

8. The network device of claim 1, wherein the master physical clock comprises a grandmaster clock.

9. A method comprising:
receiving precision time protocol (PTP) signals at a master physical clock in a primary network interface controller on a network device;
receiving the PTP signals at additional physical clocks in secondary network interface controllers on the network device; and
determining an accuracy measurement of PTP signal synchronization between the master physical clock and the additional physical clocks by executing network namespaces in the network interface controllers.

10. The method of claim 9, wherein determining the accuracy measurement of the PTP signal synchronization comprises:
generating one or more PTP queries for the master physical clock and each of the additional physical clocks; and
timestamping the PTP queries.

11. The method of claim 9, wherein the network namespace and the additional network namespaces are executed utilizing one or more master physical clock threads to simulate a plurality of PTP-enabled hops from the master physical clock to at least one of the additional physical clocks.

12. A computer-implemented method comprising:
receiving, by a reverse proxy server, a content request from a client device;
establishing, by the reverse proxy server, a communication session with a caching server responsible for providing the content;
enabling, by the reverse proxy server, direct server return (DSR) for the content request; and
sending, by the reverse proxy server, packet instructions to the caching server for directly sending the content to the client device utilizing the DSR, wherein utilizing the DSR reduces a processing overhead associated with communications between the reverse proxy server and the caching server for providing the content to the client device.

13. The computer-implemented method of claim 12, wherein receiving the content request from the client device comprises:
receiving a QUIC stream including a hypertext transfer protocol (HTTP) request for the content;
processing the HTTP request; and
determining the caching server, from among a plurality of network nodes, responsible for providing the content.

14. The computer-implemented method of claim 12, wherein establishing the communication session with the caching server comprises forwarding the content request from the client device to the caching server.

15. The computer-implemented method of claim 12, wherein enabling the DSR for the content request comprises:
receiving metadata and cached HTTP response headers from the caching server; and
determining, based on the metadata and the cached HTTP response headers that the content request is eligible for the DSR.

16. The computer-implemented method of claim 12, wherein enabling the DSR enabling comprises enabling the DSR at the layer 7 application layer.

17. The computer-implemented method of claim 12, wherein sending the packet instructions to the caching server for directly sending the content to the client device utilizing DSR comprises sending an HTTP body transmission comprising the packet instructions to the caching server.

18. The computer-implemented method of claim 17, wherein sending the HTTP body transmission comprises:
sending a group of setup packets containing instructions to setup a shared context between the reverse proxy server and the caching server, wherein the shared context comprises destination information, stream identification, encryption information, and header/packet information; and
sending a group of send packets containing instructions for the caching server to transmit QUIC data representing the requested content directly to the client device.

19. The computer-implemented method of claim 12, wherein the reverse proxy server comprises a leader node in a content delivery network.

20. The computer-implemented method of claim 12, wherein the caching server comprises a follower node in a content delivery network.
